(19) United States
(12) Patent Application Publication
(10) Pub. No.: US 2024/0421165 A1
(43) Pub. Date: Dec. 19, 2024

(54) DISPLAY PANEL AND DISPLAY DEVICE

(71) Applicant: Xiamen Tianma Optoelectronics Co., Ltd., Xiamen (CN)

(72) Inventors: Xuyang WENG, Xiamen (CN); Xiaoxia HONG, Xiamen (CN); Xuhui PENG, Xiamen (CN); Zhe PIAO, Xiamen (CN); Jiaqi KANG, Xiamen (CN); Jinmei CHEN, Xiamen (CN); Chenpeng WANG, Xiamen (CN); Meiqi ZHAO, Xiamen (CN); Pan JIN, Xiamen (CN); Hong CHEN, Xiamen (CN)

(73) Assignee: Xiamen Tianma Optoelectronics Co., Ltd., Xiamen (CN)

(21) Appl. No.: 18/750,037

(22) Filed: Jun. 21, 2024

(30) Foreign Application Priority Data
Dec. 29, 2023 (CN) 202311873259.2

(51) Int. Cl. H01L 27/12

(52) U.S. Cl. CPC H01L 27/124

(57) ABSTRACT

A display panel and a display device are provided. The display panel includes: a display region, a non-display region, and multiple drive signal lines. A fanout region and a connection terminal region are disposed in the non-display region. Multiple fanout wires are arranged in the fanout region. Multiple connection terminals are arranged in the connection terminal region. The fanout wires include a first fanout wire and a second fanout wire. The first fanout wire includes a first wire segment. The first wire segment has a width different from the width of the second fanout wire. The length of the first wire segment is equal to at least a portion of the length of the first fanout wire.

### CROSS-REFERENCE TO RELATED APPLICATION(S)

This disclosure claims priority to Chinese Patent Application No. 202311873259.2 filed with the China National Intellectual Property Administration (CNIPA) on Dec. 29, 2023, the disclosure of which is incorporated herein by reference in its entirety.

### TECHNICAL FIELD

This disclosure relates to the field of display technologies, for example, a display panel and a display device.

### BACKGROUND

As the requirements for panel display technologies are increased, the structures of display panels become more complex, resulting in an increasing number of signal lines in the display panels. For example, a touch screen is a human machine interface (HMI) technology, and is an interface component that can produce control functions by touch. The induction-type interface component that has a touch function is mounted to a display or a panel. Commonly used types include an in-cell capacitive touch screen, and the basic principle of the in-cell capacitive touch screen is to use the change of a capacitance value to sense an instruction applied from outside, respond according to the instruction and perform a corresponding operation. To detect the touch signal of the touch screen, it is required to set a large number of touch wires, and required to connect the touch wires to a touch integrated circuit (IC) by connection lines.

There are a huge number of touch wires, connection lines for connecting the touch wires to a touch IC and other original wires of the display panel, and those wires occupy a large space. With the design of a conventional display panel with a narrow border, the width of a wire is narrowed down, and as a result, the impedance value of the wire exceeds an impedance threshold value set by a touch chip, which causes power consumption and heating issues of the display panel, and adversely affects the touch function of the display panel.

### SUMMARY

A display panel and a display device are provided.

A display panel is provided, which includes a display region and a non-display region at least partially surrounding the display region.

Multiple drive signal lines are arranged in the display region and extend to the non-display region. In the display region, the drive signal lines extend in a first direction and are arranged in a second direction, and the first direction is intersected with the second direction.

A fanout region and a connection terminal region are disposed in the non-display region. The connection terminal region is disposed at a side of the fanout region away from the display region. Multiple fanout wires are arranged in the fanout region. Multiple connection terminals are arranged in the connection terminal region. Each of first ends of the fanout wires is connected to a respective one of the drive signal lines, and each of second ends of the fanout wires is connected to a respective one of the connection terminals.

The fanout wires include a first fanout wire and a second fanout wire. The first fanout wire includes a first wire segment. The first wire segment has a width different from a width of the second fanout wire. A length of the first wire segment is equal to at least a portion of a length of the first fanout wire.

A display device is further provided, which includes the display panel.

### BRIEF DESCRIPTION OF DRAWINGS

FIG. 1 is a schematic structural diagram of a display panel according to an embodiment of the present disclosure;

FIG. 2 is a schematic enlarged view of a local region A1 of a fanout region of the display panel in FIG. 1;

FIG. 3 is a schematic enlarged view of a local region A2 of a display region of the display panel in FIG. 1;

FIG. 4 is another schematic enlarged view of a local region A1 of a fanout region of the display panel in FIG. 1;

FIG. 5 is another schematic enlarged view of a local region A1 of a fanout region of the display panel in FIG. 1;

FIG. 6 is another schematic enlarged view of a local region A1 of a fanout region of the display panel in FIG. 1;

FIG. 7 is a schematic diagram of the impedance of the panel resistance without fanout wire compensation being performed according to an embodiment of the present disclosure;

FIG. 8 is a schematic diagram of the impedance of the panel resistance with fanout wire compensation being performed according to an embodiment of the present disclosure;

FIG. 9 is another schematic enlarged view of a local region A1 of a fanout region of the display panel in FIG. 1;

FIG. 10 is another schematic diagram of the impedance of the panel resistance with fanout wire compensation being performed according to an embodiment of the present disclosure;

FIG. 11 is another schematic enlarged view of a local region A1 of a fanout region of the display panel in FIG. 1;

FIG. 12 is another schematic enlarged view of a local region A1 of a fanout region of the display panel in FIG. 1;

FIG. 13 is a schematic cross-sectional view taken along line b-b′ showing the structure of the local region A1 in FIG. 12;

FIG. 14 is another schematic enlarged view of a local region A1 of a fanout region of the display panel in FIG. 1;

FIG. 15 is another schematic enlarged view of a local region A1 of a fanout region of the display panel in FIG. 1;

FIG. 16 is a schematic structural diagram of another display panel according to an embodiment of the present disclosure;

FIG. 17 is a schematic structural diagram of another display panel according to an embodiment of the present disclosure;

FIG. 18 is a schematic diagram of the impedance of the panel resistance in a normal technique according to an embodiment of the present disclosure;

FIG. 19 is a schematic diagram of the impedance of the panel resistance with technique fluctuations according to an embodiment of the present disclosure;

FIG. 20 is a schematic diagram of the impedance of the panel resistance with compensation being performed according to an embodiment of the present disclosure; and

FIG. 21 is a schematic structural diagram of a display device according to an embodiment of the present disclosure.

### DETAILED DESCRIPTION

For an in-cell capacitive touch screen, there may be continuous currents flowing through capacitive sensors, such that the capacitive sensors can store electrons in horizontal and vertical directions accurately, to form a distribution of a field of capacitance on the display panel. When the field of capacitance of capacitive sensors changes due to a finger touch or a stylus touch, a touch chip (touch IC) in the display panel will accurately identify the degree and the position of the change, caused by the external factor, of a stable field of capacitance previously established, and transmits the touch or touch signal to a controller for processing.

Whether the touch IC can accurately identify the touch signal on the panel depends on whether the change degree of the field of capacitance can be precisely identified. By increasing the number of touch signal wires and reducing the time delay on transmission lines, the accuracy of touch signal recognition can be significantly improved. However, with the increase of display area of medium and large sized display panels and the rise of narrow border display screens in recent years, the space for the touch signal wires is significantly reduced, and the impedances of circuit wires continuously increase and exceed the impedance threshold value (e.g., RC threshold value) set by the touch IC, thus causing power consumption and heating issues and reducing touch performance.

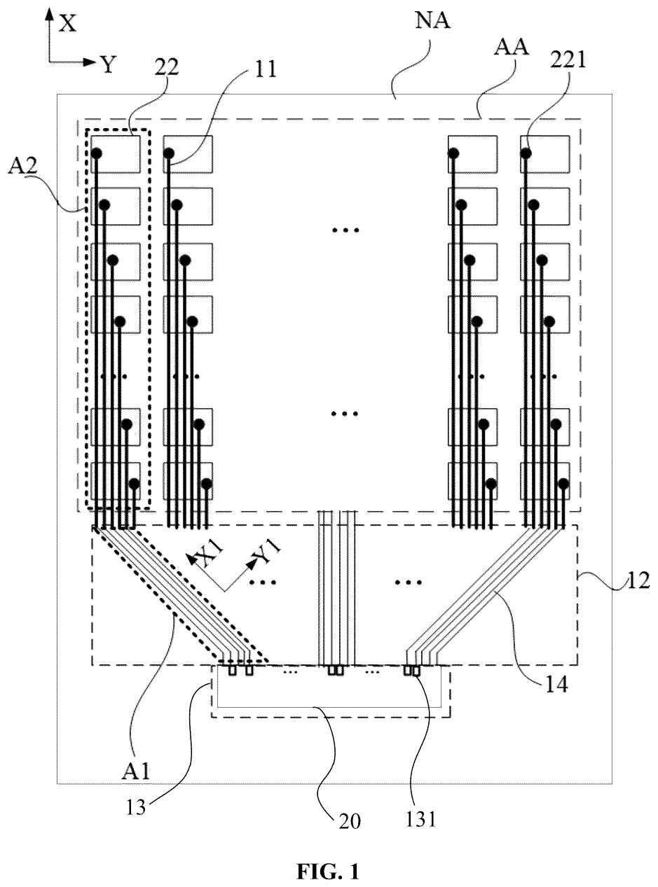

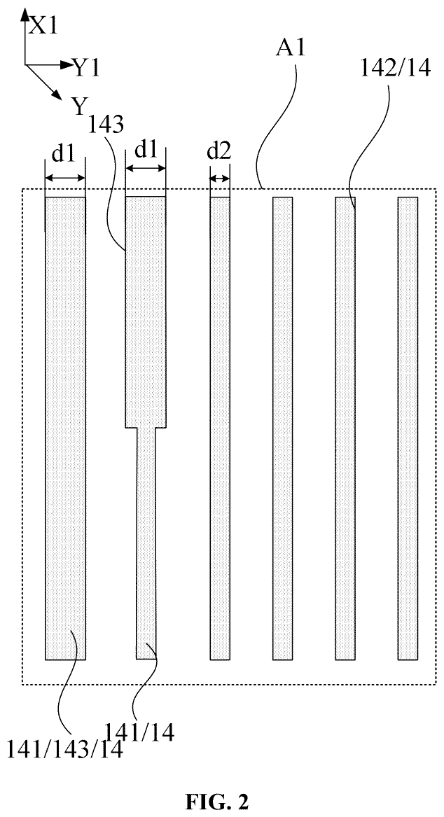

To address the above issues, a display panel is provided according to an embodiment of the present disclosure. As shown in FIG. 1, FIG. 1 is a schematic structural diagram of a display panel according to an embodiment of the present disclosure. FIG. 2 is a schematic enlarged view of a local region A1 of a fanout region of the display panel in FIG. 1. The display panel includes a display region AA and a non-display region NA at least partially surrounding the display region AA.

Multiple drive signal lines 11 are arranged in the display region AA and extend to the non-display region NA. At least in the display region AA, the drive signal lines 11 extend in a first direction X and are arranged in a second direction Y, and the first direction X is intersected with the second direction Y.

A fanout region 12 and a connection terminal region 13 are arranged in the non-display region NA. The connection terminal region 13 is arranged at a side of the fanout region 12 away from the display region AA. Multiple fanout wires 14 are arranged in the fanout region 12. Multiple connection terminals 131 are arranged in the connection terminal region 13. Each of first ends of the fanout wires 14 is connected to a respective one of the drive signal lines 11, and each of second ends of the fanout wires 14 is connected to a respective one of the connection terminals 131.

The fanout wires 14 include a first fanout wire 141 and a second fanout wire 142. The first fanout wire 141 includes a first wire segment 143. The first wire segment 143 has a width different from the width of the second fanout wire 142. The length of the first wire segment 143 is equal to at least a portion of the length of the first fanout wire 141.

In the embodiment of the present disclosure, the display region of the display panel includes the drive signal lines that extend in the first direction and are arranged in the second direction, and the non-display region includes the fanout region and the connection terminal region. The connection terminal region includes multiple connection terminals. First ends of the fanout wires in the fanout region are connected to the drive signal lines, respectively, and second ends of the fanout wires in the fanout region are connected to the corresponding connection terminals, respectively. The fanout wires include the first fanout wire and the second fanout wire, the first fanout wire includes the first wire segment, and the first wire segment has a width different from the width of the second fanout wire. Thus in this embodiment, the width of the first wire segment can be adjusted according to the impedance value of the drive signal line and the impedance value of the first fanout wire. For example, when the impedance value of the drive signal line or the impedance value of the first fanout wire is relatively large, the width of the first wire segment may be increased, to allow the width of the first wire segment to be greater than the width of the second fanout wire. With this embodiment, the panel impedance can be effectively reduced, the drive performance of the drive signal line can be improved, and the issue of impedance delay can be effectively prevented. In addition, only the first wire segments rather than all of the fanout wires are widened, thereby ensuring the narrow border configuration of the display panel.

The preceding is the core idea of the present disclosure. Hereinafter, the technical solutions in embodiments of the present disclosure will be described clearly and completely in conjunction with drawings in the embodiments of the present disclosure. Based on the embodiments of the present disclosure, all other embodiments obtained by the person having ordinary skill in the art without making creative efforts are within the scope of the present disclosure.

As shown in FIG. 1 and FIG. 2, the display panel includes a display region AA and a non-display region NA at least partially surrounding the display region AA. In the display region AA, multiple drive signal lines 11 are arranged, and the drive signal lines 11 extend in the first direction X and are arranged in the second direction Y. The first direction X is intersected with the second direction Y. For example, the first direction X and the second direction Y may be perpendicular to each other. In the non-display region NA, a fanout region 12 and a connection terminal region 13 are provided. For example, the fanout region 12 and the connection terminal region 13 are provided in the non-display region NA on one side of the display region AA, and the fanout region 12 is arranged between the display region AA and the connection terminal region 13. Multiple fanout wires 14 are arranged in the fanout region 12, and the multiple fanout wires 14 are distributed in sequence in the second direction Y. The connection terminal region 13 includes multiple connection terminals 131, and the multiple connection terminals 131 may be distributed in sequence in the second direction Y. In some embodiments, the connection terminal 131 may be configured to connect to a driver chip 20; and alternatively, the connection terminal 131 may be configured to connect to a driver chip 20 by a flexible printed circuit board, so that the connection terminal 131 can acquire a drive signal, and transmit the drive signal to a corresponding drive signal line 11 by a corresponding fanout wire 14. In some embodiments, if the drive signal is a touch trigger signal, the drive signal line 11 is a touch signal line. When the touch trigger signal is transmitted to the drive signal line 11 by a corresponding fanout wire 14, the drive signal line 11 is configured to provide the touch trigger signal for a touch electrode 22. Furthermore, when a finger or a stylus causes a change of capacitance between the finger or the stylus and the touch electrode 22, the touch electrode 22 transmits a touch detection signal to the connection terminal region 13 by the drive signal line 11 and the corresponding fanout wire 14, thereby implementing a touch function.

Referring to FIG. 2, it is to be noted that FIG. 2 is an enlarged schematic structural diagram of multiple adjacent fanout wires 14 in the fanout region 12. As shown in FIG. 1, it may be seen that multiple adjacent fanout wires 14 may be considered as being approximately parallel to each other, and the fanout wires 14 extend in a third direction X1, and are arranged in a fourth direction Y1 in sequence. The third direction X1 is intersected with the first direction X, and the fourth direction Y1 is intersected with the second direction Y. It is to be noted that extension directions (the third direction X1) of the fanout wires 14 in different regions on the display panel are different. Therefore, distribution directions (the fourth direction Y1) of the fanout wires 14 are also different, that is, the third direction X1 and the fourth direction Y1 are at variable angles, and are not fixed directions. Since the multiple adjacent fanout wires 14 tends to be of the same length, the enlarged view of the multiple adjacent fanout wires 14 is approximately as shown in FIG. 2. In addition, the above local region A1 is not limited to the outermost fanout wire 14 in the fanout wires 14, and may refer to any multiple adjacent fanout wires 14 in the fanout wires 14 distributed in the second direction Y. The fanout wires 14 include a first fanout wire 141 and a second fanout wire 142. A first wire segment 143 is formed in the first fanout wire 141, and the first wire segment 143 may be of the whole length of the first fanout wire 141, or may be of the partial length of the first fanout wire 141. As shown in FIG. 2, a width d1 of the first wire segment 143 is different from a width d2 of the second fanout wire 142. In FIG. 2, the width d1 of the first wire segment 143 is greater than the width d2 of the second fanout wire 142. For example, in a touch circuit, for the case where the impedance of a fanout wire 14 or the impedance of a drive signal line 11 connected to a fanout wire 14 exceeds a specified impedance, a first fanout wire 141 may be formed by widening the first wire segment 143 of the fanout wire 14, and the width d1 of the first fanout wire 141 is greater than the width d2 of the second fanout wire 142. Thus the impedance of the touch wire in which the first fanout wire 141 is located can be reduced to meet the impedance requirement of the display panel. Since it is only the first fanout line 141 which is widened and compensated, rather than all of the fanout lines 14 which are widened and compensated, the space requirement for the border can be reduced, thereby meeting the requirement of design of narrow border. Furthermore, it is also because only part of the fanout wires 14 are compensated in width, and an abrupt change of the impedance of the display panel is avoided, thus preventing abrupt change of the impedance from adversely affecting touch performance. It is to be noted that, to meet the impedance requirement of the display panel, in this embodiment, not only the first wire segment 143 is controlled to be wider than the second fanout wire 142 when the touch wire impedance is excessively large, but also the first wire segment 143 is controlled to be narrower than the second fanout wire 142 when the touch wire impedance is excessively small, to keep the touch wire impedance stable. This embodiment sets no limitation on the magnitude relationship of values between d1 and d2.

Referring to FIG. 1 and FIG. 2, in some embodiments, the sum of the resistance of a fanout wire 14 and the resistance of the drive signal line 11 connected to the fanout wire 14 may serve as a panel resistance of the fanout wire 14; and the panel resistance of the first fanout wire 141 is less than or equal to a set impedance threshold value.

In this embodiment, a fanout wire 14 and a drive signal line 11 connected to the fanout wire 14 form a touch wire, and a total resistance of the touch wire is the sum of a resistance Rfanout of the fanout wire 14 and a resistance Raa of the drive signal line 11 connected to the fanout wire 14. In this embodiment, the total resistance of the touch wire may be referred to as a panel resistance Rtotal of the fanout wire 14. In other words, Rtotal=Raa+Rfanout. In this embodiment, if the panel resistance Rtotal of the second fanout wire 142 is less than or equal to the set impedance threshold value, no special setting is required for the width d2 of the second fanout wire 142. However, if the width of the first fanout wire 141 is the same as the width of the second fanout wire 142, the panel resistance Rtotal of the first fanout wire 141 may perhaps be greater than the set impedance threshold value. In this case, the width of the first wire segment 143 of the first fanout wire 141 may be increased to reduce Rfanout, to further meet that the panel resistance Rtotal of the first fanout wire 141 is less than or equal to the set impedance threshold value, thereby meeting the touch performance requirement, avoiding a delay in the touch circuit caused by a too large impedance value and improving sensitivity and accuracy of the touch screen. For example, the set impedance threshold value may be 8.5 kΩ. In some embodiments, there are three factors that may influence the impedance of a panel wire: a sheet resistance p (its magnitude depends on technique capability), the width W of the wire, and the length L of the wire, that is, the impedance of a panel wire is denoted as R=(ρ×L)/W. If the sheet resistance p in this embodiment is a fixed value, compensation is made for the panel wire with a large length L, that is, by increasing W, to achieve a reduction in the resistance R. In this embodiment, compensation is performed only for a small number of wire parts exceeding a specified value, to minimize space requirements of additional wires and meet narrow border requirements.

Furthermore, as shown in FIG. 1, for each touch electrode 22, a drive signal line 11 is correspondingly provided, and the touch electrode 22 is connected to a corresponding drive signal line 11 by a via hole 221. In addition, for touch electrodes 22 of the same column, a shorter drive signal line 11 corresponds to a touch electrode 22 closer to the fanout region 12, and a longer drive signal line 11 corresponds to a touch electrode 22 farther away from the fanout region 12. That is, the value of the resistance Raa of the drive signal line 11 corresponding to the touch electrode 22 farther away from the fanout region 12 is relatively large, and it is known that Rtotal=Raa+Rfanout. To ensure that the panel resistance Rtotal of the fanout wire 14 is within a specified range, the width d1 of the first fanout wire 141 connected to a touch electrode 22 farther away from the fanout region 12 is larger, and the width d1 of the first fanout wire 141 connected to a touch electrode 22 closer to the fanout region 12 is smaller, to balance impedance values of the touch wires on the entire display panel, prevent abrupt changes of the impedance values of the touch wires, prevent the touch function from being interfered, and improve reliability of the touch screen.

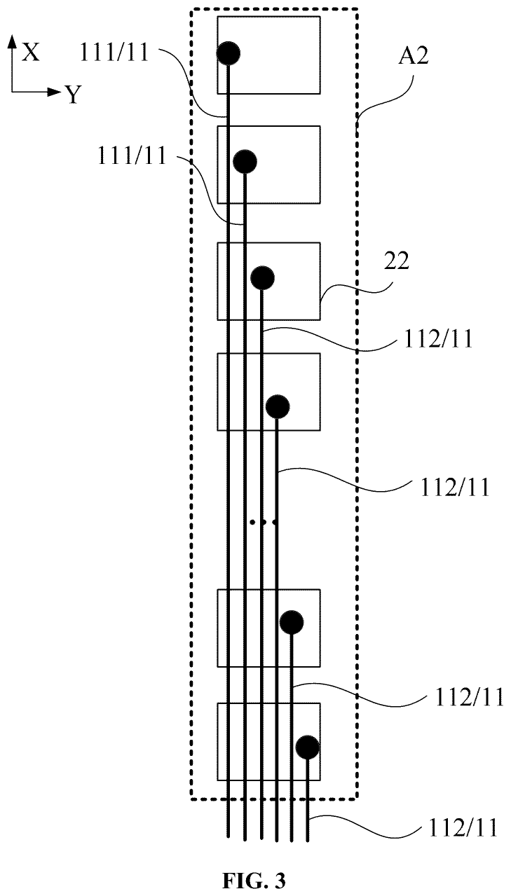

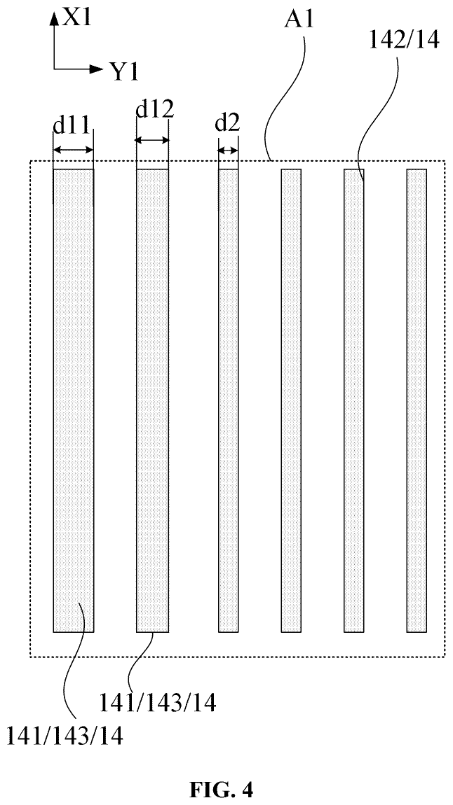

FIG. 3 is a schematic enlarged view of a local region A2 of a display region of the display panel in FIG. 1, and FIG. 4 is another schematic enlarged view of a local region A1 of a fanout region of the display panel in FIG. 1. In this embodiment, the local region A2 includes multiple drive signal lines 11, and the local region A1 includes multiple fanout wires 14. The drive signal lines 11 in the local region A2 are connected to the fanout wires 14 in the local region A1 in a one-to-one correspondence manner. For example, six drive signal lines 11 are arranged in the local region A2, and six fanout wires 14 are arranged in the local region A1. Referring to FIG. 1 to FIG. 3, in some embodiments, the drive signal lines 11 may include a first drive signal line 111 and a second drive signal line 112. The first drive signal line 111 is connected to the first fanout wire 141; and the second drive signal line 112 is connected to the second fanout wire 142. If the resistance of a first drive signal line 111 is large, the width of a first wire segment 143 is large, to allow the panel resistance of the first fanout wire 141 to be less than the set impedance threshold value. If the resistance of a first drive signal line 111 is small, the width of a first wire segment 143 is small, to allow the panel resistance of the first fanout wire 141 to be less than the set impedance threshold value.

In this embodiment, the fanout wires 14 are divided into first fanout wires 141 and second fanout wires 142 according to whether the fanout wires 14 have first wire segments 143. Therefore, the drive signal lines 11 may be divided into first drive signal lines 111 and second drive signal lines 112. The first drive signal line 111 is correspondingly connected to the first fanout wire 141, and the second drive signal line 112 is correspondingly connected to the second fanout wire 142. FIG. 3 shows the drive signal lines 11 corresponding to a column of touch electrodes 22. It can be seen from FIG. 3 that, in a first direction X from the display region AA to the fanout region 12, the lengths of drive signal lines 11 connected to touch electrodes 22 gradually decrease, and the resistances Raa corresponding to the drive signal lines 11 gradually decrease. For example, in this embodiment, the panel resistances Rtotal corresponding to four drive signal lines 11 with low resistances Raa are within a specified range, and in this case, the widths d2 of the fanout wires 14 connected to the drive signal lines 11 are not required to be adjusted. The four drive signal lines 11 with low resistances Raa are used as second drive signal lines 112, and are connected to four second fanout wires 142 in the local region A1 in a one-to-one correspondence manner. For two drive signal lines 11 with relatively high resistances Raa, the two drive signal lines 11 may be correspondingly connected to two first fanout wires 141 in the local region A1 in a one-to-one correspondence manner. It is to be noted that in the two first drive signal lines 111, the resistance Raa of the first drive signal line 111 connected to the touch electrode 22 away from the fanout region 12 is relatively high, and the resistance Raa of the other first drive signal line 111 is relatively low. To balance the impedances of the two touch wires, the first drive signal line 111 connected to the touch electrode 22 away from the fanout region 12 is connected to the first fanout wire 141 with a width d11, the other first drive signal line 111 is connected to the first fanout wire 141 with a width d12, and d11>d12. In this embodiment, lengths of the first wire segments 143 are defined to be the same, and in this case, the panel resistance Rtotal is adjusted by adjusting the width of the first wire segment 143, thereby improving the touch performance of the touch screen.

Furthermore, the drive signal lines 11 shown in FIG. 3 may also be connected to the fanout wires 14 shown in FIG. 2 in a one-to-one correspondence manner. In FIG. 2, the widths d1 of the first wire segments 143 are fixed, and the lengths of the first wire segments 143 are different. Similarly, FIG. 3 may include two first drive signal lines 111; in the two first drive signal lines 111, the first drive signal line 111 connected to the touch electrode 22 away from the fanout region 12 has a relatively high resistance Raa, and may be connected to the first fanout wire 141 in which the first wire segment 143 has a length equal to the whole length of the fanout wire, and the other first drive signal line 111 has a relatively low resistance Raa, and may be connected to the first fanout wire 141 in which the first wire segment 143 has a length equal to part of the length of the fanout wire.

In summary, in this embodiment, it is creatively proposed that the panel resistance Rtotal consists of the resistance Raa of the drive signal line 11 and the resistance Rfanout of the fanout wire 14, Rtotal=Raa+Rfanout. For example, Raa/Rfanout has a range, that is, Raa/Rfanout can be large or small. To enable the Rtotal to meet the requirement of the touch wire, if Raa is large, it is required to match a small Rfanout, and if Raa is small, Rfanout is allowed to be large. If both the Raa and the Rfanout are large, it is apt to exceed the impedance range, and in this case, it is required to compensate the Rfanout, to reduce the Rfanout, that is, the length and the width of the first wire segment 143 are adjusted to ensure that the Rtotal meets the requirement of the touch wire, preventing the impedance of the panel line from being excessively large. In addition, since the first wire segments 143 are provided only in the first fanout wires 141, the space requirement for the fanout region is relatively low, which facilitates maintaining the narrow border of the display panel.

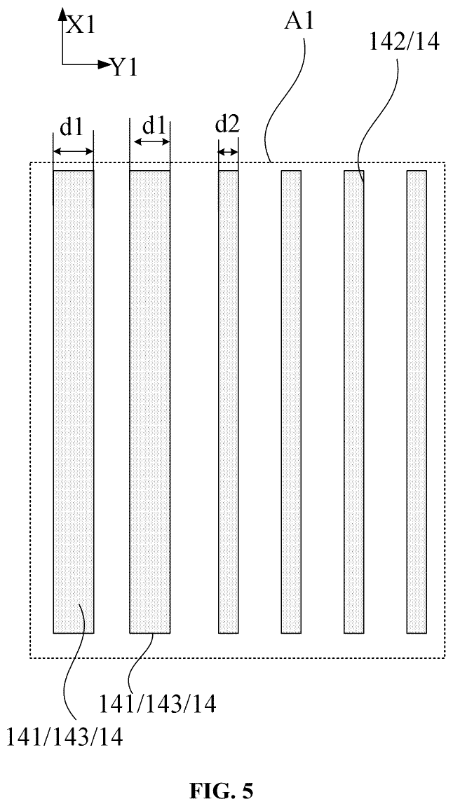

FIG. 5 is another schematic enlarged view of a local region A1 of a fanout region of the display panel in FIG. 1. In some embodiments, the first wire segment 143 may be of the whole length of the first fanout wire 141; and the width of the first fanout wire 141 is greater than the width of the second fanout wire 142. FIG. 4 shows a first fanout wire 141 and a second fanout wire 142, and the whole length of the first fanout wire 141 is used as the length of the first wire segment 143. Thus the panel resistance Rtotal of the first fanout wire 141 is adjusted by adjusting the width of the first fanout wire 141. In this embodiment, the first fanout wire 141 is used to address the issue in which the panel resistance Rtotal is greater than the set impedance threshold value, and thus the width d1 of the first fanout wire 141 is greater than the width d2 of the second fanout wire 142, to reduce the panel resistance Rtotal of the first fanout wire 141 and avoid an excessively large impedance of the panel line. In this embodiment, it is not required to consider the length of the first wire segment 143, and only required to adjust the width d1 of the first fanout wire 141, and the adjustment manner is simple. In some embodiments, as shown in FIG. 5, widths of all the first fanout wires 141 are the same, which, while ensuring that the Rtotal does not exceed the set impedance threshold value, further simplifies the process of impedance adjustment, improves the adjustment efficiency, effectively prevents an excessively large impedance of the touch wire and maintains stability of the touch function.

Further referring to FIG. 4, in some embodiments, widths of at least two first fanout wires 141 are different. In this embodiment, widths of two first fanout wires 141 are different. FIG. 4 shows two first fanout wires 141; in the two first fanout wires 141, the width of one first fanout wire 141 is d11, and the width of the other first fanout wire 141 is d12. d11 is different from d12, and thus the resistances Rfanout of the two first fanout wires 141 are different; and according to Rtotal=Raa+Rfanout, resistances Raa of the first drive signal lines 111 connected to the two first fanout wires 141 may be different. In this embodiment, by providing the first fanout wires 141 of different widths, the panel resistances Rtotal corresponding to different first fanout wires 141 can be maintained in a small range, thereby improving uniformity of impedances of the touch wires, and improving the precision of the touch screen.

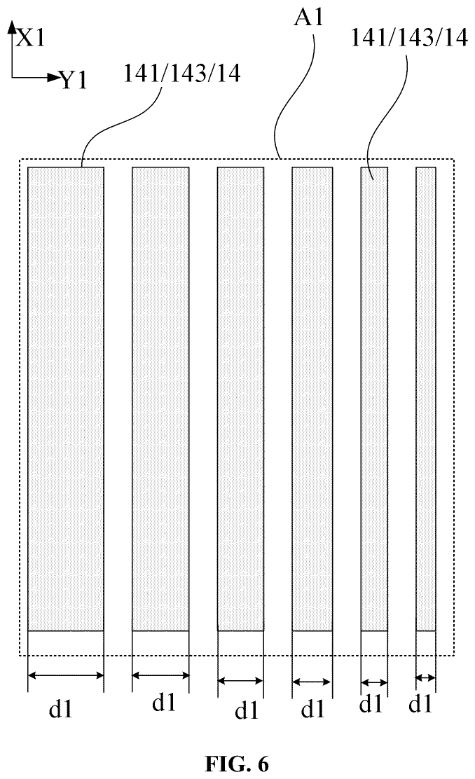

FIG. 6 is another schematic enlarged view of a local region A1 of a fanout region of the display panel in FIG. 1. The local region A1 may include multiple adjacent first fanout wires 141, and first wire segments 143 of the first fanout wires 141 are of the whole length of the first fanout wires 141. In a fourth direction Y1 and in a direction from an edge of the display panel to the center of the display panel, the widths of the first wire segments 143 are successively reduced, and the impedance compensation is performed on the panel wires whose impedances exceed the set impedance threshold value. Thus the compensation process for panel resistances is relatively smooth, which effectively prevents the wire impedance of the display panel from being changed abruptly, and improves touch performance.

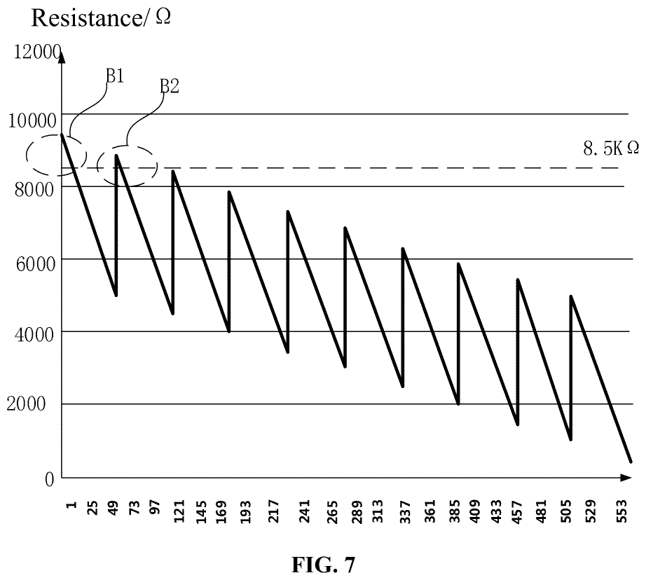

FIG. 7 is a schematic diagram of the impedance of the panel resistance without fanout wire compensation being performed according to an embodiment of the present disclosure. Referring to FIG. 6 and FIG. 7, the horizontal ordinate represents the number of fanout wires in the fourth direction Y1 and in the direction from the edge of the display panel to the center of the display panel, and the vertical ordinate represents the value of the panel resistance corresponding to a fanout wire. It can be seen from FIG. 7 that, the panel resistances of the fanout wires at positions B1 and B2 exceed 8.5K (2, and the panel wires whose impedances exceed the impedance requirement are widened, that is, W+ΔW; W is the width of the first fanout wire 141 of the panel wire whose impedance exceeds the impedance requirement, and

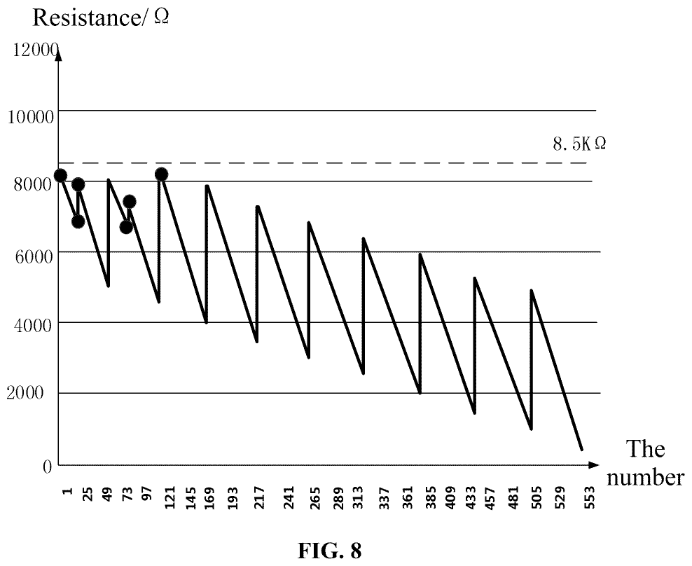

ΔW is the increasing amount of width. The increasing amount of width ΔW needs to be set depending on requirements. Different positions of the same display panel or different display panels can select different increasing amounts of width ΔW. For example, the width of a first fanout wire 141 in the position B1 in this embodiment is compensated from 3 μm to 3.6 μm, and the width of a first fanout wire 141 in the position B2 in this embodiment is compensated from 3 μm to 3.4 μm. 20 first fanout wires 141 in the position B1 are compensated, and 10 first fanout wires 141 in the position B2 are compensated. The 20 first fanout wires 141 in the position B1 may have widths that are increased successively (in the direction from the 553^{th} fanout wire to the first fanout wire), for example, the widths of the first fanout wires 141 are 3.03 μm, 3.06 μm, and 3.09 μm in sequence till 3.6 μm. FIG. 8 is a schematic diagram of the impedance of the panel resistance with fanout wire compensation being performed according to an embodiment of the present disclosure. By means of width compensation, the wire impedance can meet the requirement (<8.5 kΩ). Because the compensated first fanout wires 141 are only a small number of fanout wires 14, widening of all fanout wires 14 is avoided, and space is saved, thereby achieving narrow border.

Further referring to FIG. 2, in some embodiments, the first wire segment 143 may be of the partial length of the first fanout wire 141, and the width of the first wire segment 143 is greater than the width of the second fanout wire 142. The first wire segment 143 may be of the partial length of the first fanout wire 141, and the width d1 of the first wire segment 143 is greater than the width d2 of the second fanout wire 142. Thus, in this embodiment, compensation for the panel resistance of the first fanout wire 141 may be performed by controlling the width d1 of the first wire segment 143 fixed and adjusting the length of the first wire segment 143. This compensation manner is more intuitive, and in this compensation manner, a compensation size is easily obtained according to the length of the first wire segment 143, thereby effectively maintaining the panel resistance of the first fanout wire to be less than the set impedance threshold value, and improving touch performance of the display panel.

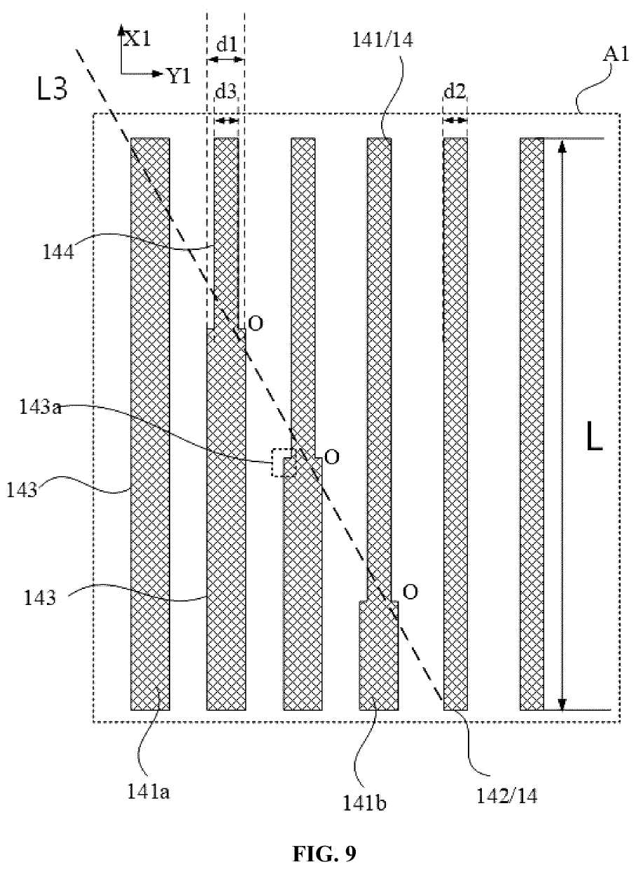

FIG. 9 is another schematic enlarged view of a local region A1 of a fanout region of the display panel in FIG. 1. In some embodiments, multiple adjacent first fanout wires 141 may be arranged in the fourth direction Y1. The lengths of first wire segments 143 of the multiple adjacent first fanout wires 141 gradually decrease in the fourth direction Y1 and in the direction from the edge to the center of the display panel. The panel wires whose impedances exceed the set impedance threshold value are compensated, and thus the process of compensation for the panel resistances is relatively smooth, thereby effectively avoiding abrupt change of wire impedances of the display panel, and improving touch performance.

In some embodiments, N adjacent first fanout wires 141 may be provided in the fourth direction Y1; and the N adjacent first fanout wires 141 each have a length L. In the fourth direction Y1 and in the direction from the edge of the display panel to the center of the display panel, a first wire segment 143 of an i-th first fanout wire in the N adjacent first fanout wires 141 has a length, L×(N+1−i)/N, and 1≤i≤N; i and N are positive integers; and N≥2.

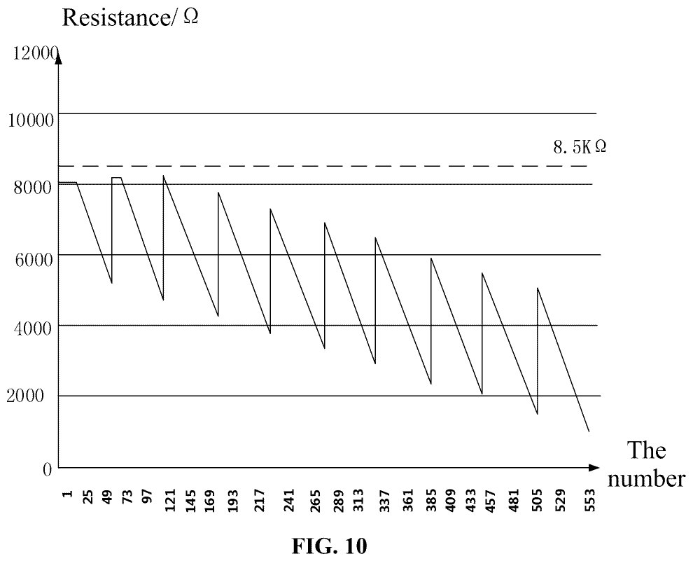

In this embodiment, impedance compensation is also performed on the wires having excessive impedances; however, the compensation is not performed on the whole lengths of the wires, but in an equal proportion manner. As shown in FIG. 9, if it is required to compensate adjacent N first fanout wires 141, and the first fanout wires 141 each have a length L, in the fourth direction Y1 and in the direction from the edge of the display panel to the center of the display panel, a first wire segment 143 of an i-th first fanout wire in the N adjacent first fanout wires 141 has a length, L×(N+1−i)/N, and then a length difference between the first wire segments 143 of two adjacent first fanout wires is L/N. For example, it is assumed that 10 first fanout wires 141 each having a length L are required to be compensated; the compensation range of the first wire is 10/10×L, that is, 100% L, and the whole length of the wire is to be compensated; the compensation range of the second wire is (10-1)/10×L, that is, 90% L; and the compensation range of the last wire is (10-9)/10×L, that is, 10% L. In the 10 first fanout wires 141 to be compensated, the impedance difference between the compensated adjacent first fanout wires 141 is 10% L, and the impedance difference between the last compensated wire, that is an N-th first fanout wire 141, and the wire without being compensated (a second fanout wire 142) is also 10%. In this case, there is no abrupt change between impedances of adjacent fanout wires 14 (especially, between the first fanout wire 141 and the adjacent second fanout wire 142), and all the changes are of gradual change. As shown in FIG. 10, FIG. 10 is another schematic diagram of the impedance of the panel resistance with fanout wire compensation being performed according to an embodiment of the present disclosure. Compared with the schematic diagram of the compensated panel resistance shown in FIG. 8, the impedances that originally have serrated abrupt changes become smoother in FIG. 10, an impedance difference between adjacent fanout wires 14 further decreases, touch is more sensitive, and touch performance is improved.

On the basis of the foregoing embodiment, referring to FIG. 9, for the N adjacent first fanout wires 141 that are required to be compensated, a head end of the first one 141a of the N first fanout wires is connected to a tail end of a second fanout wire 142 adjacent to the last one 141b of the N first fanout wires through a line (or a tail end of the first one 141a of the N first fanout wires is connected to a head end of the second fanout wire 142 adjacent to the last one 141b of the N first fanout wires through a line), and intersection points O of the connecting line L3 and the middle N−1 first fanout wires are compensation points with equal proportional difference, that is, boundary points of the first wire segments 143 and other uncompensated portions. Namely, the difference between the proportions corresponding to two adjacent compensation points may be a fixed difference. With this embodiment, the issue of abrupt change between impedances of compensated wires and uncompensated wires (first fanout wires 141 and second fanout wires 142) can be significantly improved, difficulty in debugging a touch IC and an active stylus can be reduced, and performance of the active stylus can be improved. The foregoing method of the connecting line is simple and convenient, and with the method, the proportional compensation points can be quickly delimited to achieve uniform transition of wire impedances. The wire compensation quantity, wire compensation width and wire compensation proportion may be adjusted according to different architectures. Furthermore, in addition to the method of the connecting line L3 described above, the above compensation points with equal proportional difference may also be delimited by an inclined line with a fixed slope in this embodiment, and this embodiment sets no special limitation on a value of the slope and a positive or negative value of the slope.

Further referring to FIG. 9, in some embodiments, the first fanout wire 141 may further include a second wire segment 144. The width d1 of the first wire segment 143 is greater than a width d3 of the second wire segment 144, and the width d3 of the second wire segment 144 is the same as the width d2 of the second fanout wire 142. In this embodiment, the first fanout wire 141 includes a first wire segment 143 and a second wire segment 144 which are connected to each other, and the width d1 of the first wire segment 143 is greater than the width d3 of the second wire segment 144. For example, the width d3 of the second wire segment 144 may be the same as the width d2 of the second fanout wire 142. In this embodiment, the width d3 of the second wire segment 144 is the same as the width d2 of the second fanout wire 142, and in this case, when widening the first fanout wire 141 for compensation, it is not required to design the second wire segment 144, thereby further facilitating convenience of the compensation process, and improving performance of the active stylus.

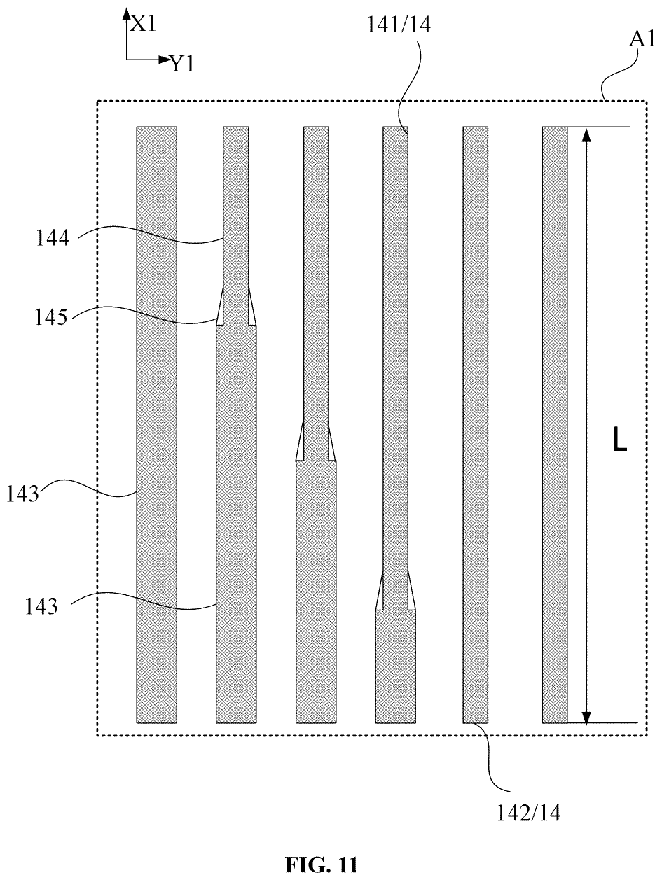

FIG. 11 is another schematic enlarged view of a local region A1 of a fanout region of the display panel in FIG. 1. In some embodiments, on the same first fanout wire 141, the first wire segment 143 may be connected to the second wire segment 144 by a bevel 145. When widening the first fanout wire 141 for compensation, if the first wire segment 143 is of only the partial length of the first fanout wire 141, a width difference is present between the first wire segment 143 and the second wire segment 144, especially at the position where the first wire segment 143 is connected to the second wire segment 144. The width difference is apparent, for the first wire segment 143 has a right angle (sharp angle), as shown in FIG. 9. Electrostatic aggregation is apt to be caused at the right angle 143a, and issues such as electrostatic breakdown are apt to occur. In this embodiment, the bevel 145 is formed between the first wire segment 143 and the second wire segment 144, which effectively prevents electrostatic aggregation, and improves security performance of the touch wires and the entire display panel.

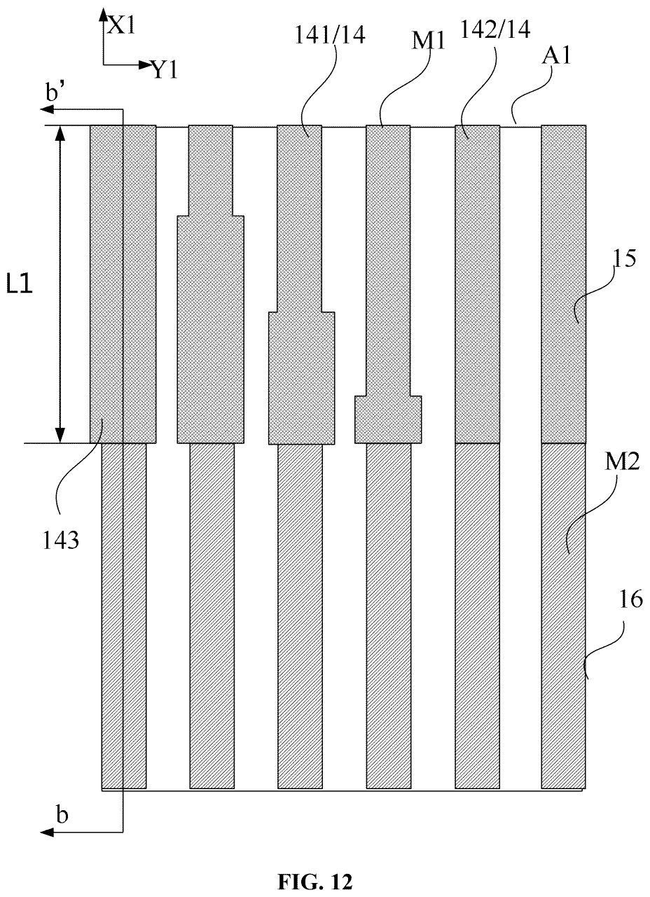

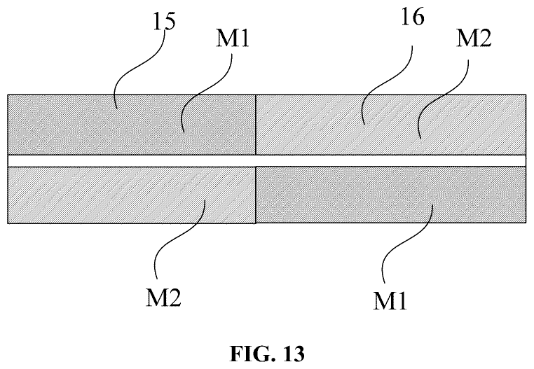

FIG. 12 is another schematic enlarged view of a local region A1 of a fanout region of the display panel in FIG. 1. FIG. 13 is a schematic cross-sectional view taken along line b-b′ showing the structure of the local region A1 in FIG. 12. In some embodiments, the display panel may include a first metal layer M1 and a second metal layer M2. The fanout wire 14 includes a first wire part 15 and a second wire part 16. The first wire part 15 is arranged in the first metal layer M1. The second wire part 16 is arranged in the second metal layer M2. The first wire part 15 and the second wire part 16 are connected by a connection hole between the first metal layer M1 and the second metal layer M2.

To further save space in the fanout region 12 and improve signal transmission capability of the fanout wire 14, in this embodiment, the fanout wire 14 is formed by overlapping the first metal layer M1 and the second metal layer M2, and electrical connection between the first metal layer M1 and the second metal layer M2 is established by the connection hole. As shown in FIG. 12, the fanout wire 14 includes a first wire part 15 and a second wire part 16, the first wire part 15 is arranged in the first metal layer M1, and the second wire part 16 is arranged in the second metal layer M2. In this embodiment, the fanout wire 14 can be compensated also by widening the first wire segment 143, to reduce the panel impedance. In addition, the fanout wire 14 formed by overlapping the two metal layers has a relatively low impedance. Thus the width or length of the first wire segment 143 can be reduced, and even the number of the first fanout wires 141 can be reduced, thereby further reducing the space occupied by the fanout wires 14 in the fanout region 12, and facilitating the narrow border configuration. In this embodiment, impedance compensation can be performed only for the first metal layer M1, or impedance compensation can be performed only for the second metal layer M2, or impedance compensation can be performed for both the first metal layer M1 and the second metal layer M2.

Further referring to FIG. 12, impedance compensation can be performed only for the first metal layer M1. In some embodiments, the first wire segment 143 may be arranged in the first wire part 15 of the first fanout wire 141. N adjacent first fanout wires 141 are provided in the fourth direction Y1. First wire parts 15 of the N adjacent first fanout wires 141 each have a length L1. In the fourth direction Y1 and in the direction from the edge of the display panel to the center of the display panel, a first wire segment 143 in a first wire part 15 of an i-th first fanout wire 141 in the N adjacent first fanout wires 141 has a length, L1×(N+1−i)/N, and 1≤i≤N; i and N are positive integers; and N≥2.

For the N first fanout wires 141 to be compensated, the to-be-compensated length of an i-th wire is longer or shorter than the to-be-compensated length of an (i+1)-th wire by L1/N. L1 is the length of the first metal layer M1 (first wire part 15) in the fanout wire 14. For example, it is assumed that 10 first fanout wires 141 each having a length L1 are required to be compensated, the compensation range of the first wire in the 10 first fanout wires 141 is 10/10×L1, that is, 100% L1, and the whole length of the wire is to be compensated; the compensation range of the second wire is (10-1)/10×L1, that is, 90% L1; and the compensation range of the last first fanout wire is (10-9)/10×L1, that is, 10% L1. In the 10 first fanout wires 141 to be compensated, the impedance difference between the compensated adjacent wires is 10%, and the impedance difference between the last compensated wire and its adjacent wire without being compensated (a second fanout wire 142) is also 10%. In this case, there is no abrupt change between impedances of adjacent fanout wires 14, and all the changes are of gradual change. Compared with a fanout wire 14 formed by single-layer metal, the fanout wire 14 formed by double-layer metal in this embodiment has a relatively low impedance itself, and with the compensation method described in this embodiment, the impedance difference is further reduced and the touch performance is further improved.

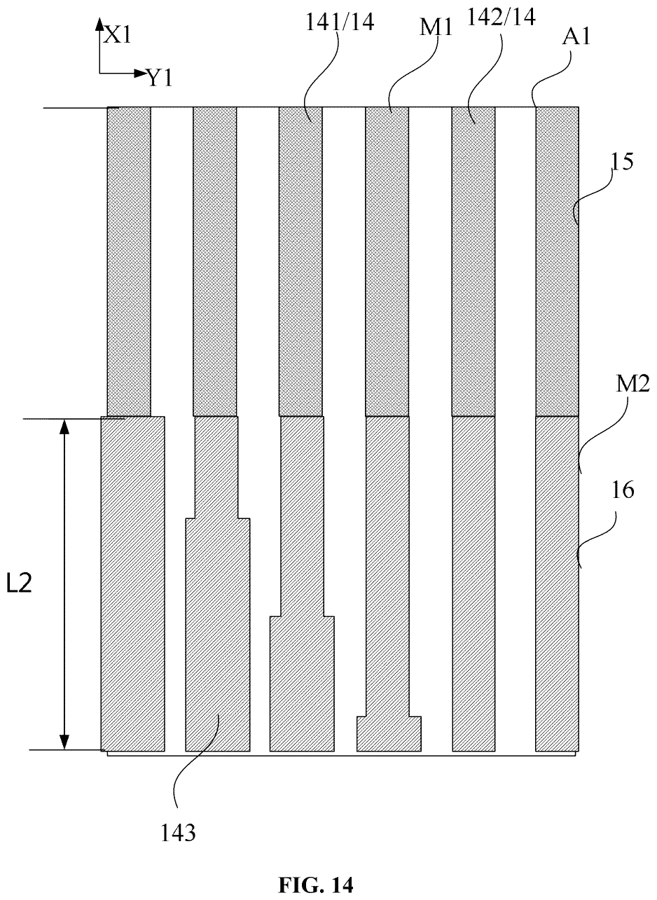

FIG. 14 is another schematic enlarged view of a local region A1 of a fanout region of the display panel in FIG. 1. Impedance compensation can be performed only for the second metal layer M2. In some embodiments, the first wire segment 143 may be arranged in the second wire part 16 of the first fanout wire 141. N adjacent first fanout wires 141 are provided in the fourth direction Y1. Second wire parts 16 of the N adjacent first fanout wires 141 each have a length L2. In the fourth direction Y1 and in the direction from the edge of the display panel to the center of the display panel, a first wire segment 143 in a second wire part 16 of an i-th first fanout wire in the N adjacent first fanout wires 141 has a length, L2×(N+1−i)/N, and 1≤i≤N; i and N are positive integers; and N≥2.

Similarly, for the N first fanout wires 141 to be compensated, the to-be-compensated length of an i-th wire is longer or shorter than the to-be-compensated length of an (i+1)-th wire by L2/N. L2 is the length of the second metal layer M2 (second wire part 16) in the fanout wire 14. Similarly, it is assumed that 10 first fanout wires 141 each having a length L2 are required to be compensated, the compensation range of the first wire in the 10 first fanout wires 141 is 10/10×L2, that is, 100% L2, and the whole length of the wire is to be compensated; the compensation range of the second wire in the 10 first fanout wires 141 is (10-1)/10×L2, that is, 90% L2; and the compensation range of the last wire in the 10 first fanout wires 141 is (10-9)/10×L2, that is, 10% L2. In the 10 first fanout wires 141 to be compensated, the impedance difference between the compensated adjacent wires 141 is 10%, and the impedance difference between the last compensated wire and the wire without being compensated is also 10%. In this case, there is no abrupt change between impedances of adjacent wires, and all the changes are of gradual change. In addition, in this embodiment, the fanout wire 14 is formed by double-layer metal, thereby further reducing the impedance difference and improving the touch performance.

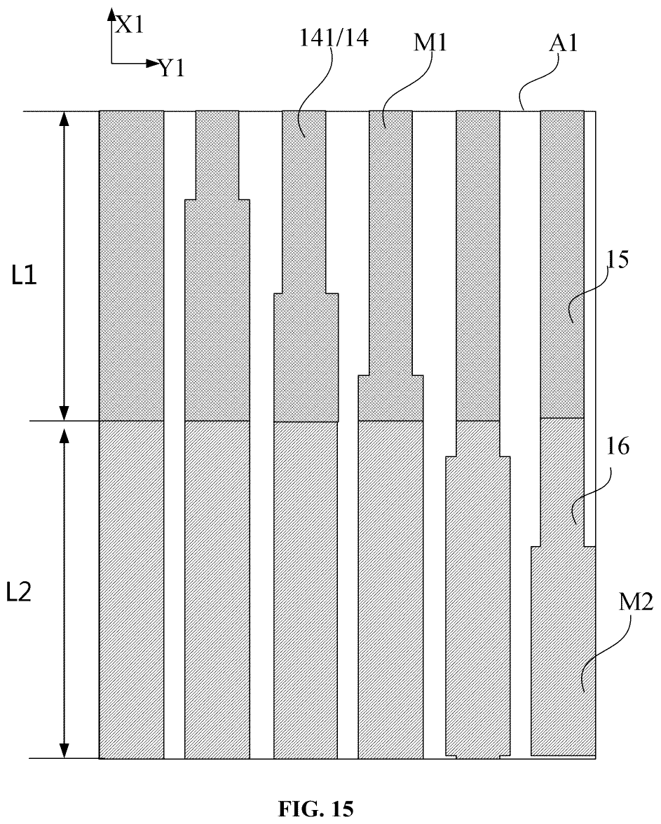

FIG. 15 is another schematic enlarged view of a local region A1 of a fanout region of the display panel in FIG. 1. Impedance compensation can be performed for both the first metal layer M1 and the second metal layer M2. In some embodiments, the first wire segment 143 may be arranged in both the first wire part 15 and the second wire part 16 of the first fanout wire 141. N adjacent first fanout wires 141 are provided in the fourth direction Y1. First wire parts 15 of the N adjacent first fanout wires 141 each have a length L1 and second wire parts 16 of the N adjacent first fanout wires 141 each have a length L2. In the fourth direction Y1 and in the direction from the edge of the display panel to the center of the display panel, a first wire segment 143 of an i-th first fanout wire in the N adjacent first fanout wires 141 has a length, (L1+L2)×(N+1−i)/N, and 1≤i≤N; i and N are positive integers; and N≥2.

For the N first fanout wires 141 to be compensated, the to-be-compensated length of an i-th wire is longer or shorter than the to-be-compensated length of an (i+1)-th wire by (L1+L2)/N. (L1+L2) is the sum of the length of the first metal layer M1 (first wire part 15) and the length of the second metal layer M2 (second wire part 16) in the fanout wire 14. For example, it is assumed that ten fanout wires 14 each having a length (L1+L2) are required to be compensated, the compensation range of the first wire in the ten fanout wires 14 is 10/10×(L1+L2), that is, 100% (L1+L2), and the whole length of the wire is to be compensated; the compensation range of the second wire in the ten fanout wires 14 is (10-1)/10×(L1+L2), that is, 90% (L1+L2); and the compensation range of the last wire in the ten fanout wires 14 is (10-9)/10×(L1+L2), that is, 10% (L1+L2). In this embodiment, the fanout wire 14 is formed by double-layer metal, thereby further reducing the impedance difference and improving the touch performance. It is to be noted that when the first metal layer M1 and the second metal layer M2 overlap, impedance differences are reduced, and touch performance is improved; moreover, when the first metal layer M1 and the second metal layer M2 overlap, width compensation is also adopted, thereby preventing the abrupt change of the impedance and improving reliability of the touch screen.

In some embodiments, the first metal layer M1 may also serve as a gate layer of a pixel driving circuit, and the second metal layer M2 may also serve as a source and drain layer of the pixel driving circuit. In this embodiment, the first metal layer M1 may also serve as a gate layer of a pixel driving circuit, and the second metal layer M2 may also serve as a source and drain layer of the pixel driving circuit. In this case, the fanout wire 14 is formed by using the same technique as the gate layer and the source and drain layer, thereby improving drive performance of the drive signal line while reducing the impedance of the touch wire. In addition, the first metal layer M1 and the second metal layer M2 are arranged in an overlapping manner; thus space of the fanout region is effectively saved, and narrow border of the display panel is ensured. In this embodiment, the display panel may further include multiple scan signal lines, multiple data signal lines, pixel driving circuits, and display electrodes. A pixel driving circuit is connected to a scan signal line, a data signal line, and a display electrode. The scan signal line is configured to transmit a scan signal to the pixel driving circuit, the data signal line is configured to provide a data signal for the pixel driving circuit, and the pixel driving circuit, controlled by the scan signal and the data signal, provides a display signal to the display electrode, to ensure that the display panel can be normally displayed. Further, the pixel driving circuit may include multiple thin-film transistors, and the thin-film transistor includes an active layer, a gate, a source, and a drain. The first metal layer M1 in this embodiment is configured to form the gate of the thin-film transistor, and the second metal layer M2 in this embodiment is configured to form the source and drain of the thin-film transistor. The display panel in this embodiment may be, but is not limited to, a liquid crystal display panel, an organic light-emitting display panel, a Micro light-emitting diode (LED) display panel, or the like.

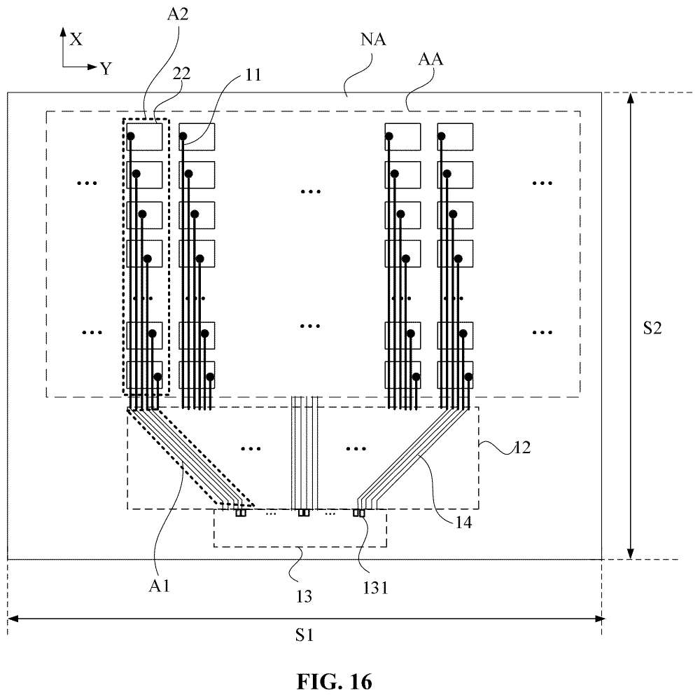

FIG. 16 is a schematic structural diagram of another display panel according to an embodiment of the present disclosure. In some embodiments, a length S1 of the display panel in the second direction Y may be greater than a length S2 of the display panel in the first direction X. The fanout region 12 and the connection terminal region 13 are arranged in an edge region of the display panel extending in the second direction Y. If the length S1 of the display panel in the second direction Y is greater than the length S2 of the display panel in the first direction X, the display panel is designed as a landscape panel. The landscape panel is longer in the second direction Y, a portrait panel is shorter in the second direction Y, so the fanout wire 14 of the landscape panel is longer. Therefore, the impedance of the landscape panel is more apt to exceed the threshold value than that of the portrait panel. This embodiment may be used in a scenario in which the impedance of a landscape panel apparatus is to be reduced, thereby effectively avoiding impedance delay (e.g., RC delay) caused by an increase of length of touch circuit wires, and improving sensitivity and accuracy of the touch screen of the landscape panel. In addition, only some of the fanout wires are widened, thereby ensuring the narrow border configuration of the display panel. Furthermore, regardless of a landscape panel or a portrait panel, this embodiment can effectively prevent the impedance from overshooting and improve touch performance.

Further referring to FIG. 1 and FIG. 2, in some embodiments, in the second direction Y, the first fanout wire 141 may be arranged at a side of the second fanout wire 142 away from the center of the display panel. In the fanout region 12, in the second direction Y and in the direction from the edge of the display panel to the center of the display panel, the first fanout wires 141 in the multiple adjacent fanout wires 14 may be arranged at a side of the second fanout wires 142 away from the center of the display panel. In one aspect, in the direction from the edge of the display panel to the center of the display panel, the drive signal lines 11 connected to the touch electrodes 22 of the same column have lengths from large to small, so the resistances Raa of the drive signal lines 11 gradually decrease; therefore, to prevent the touch wire impedances from being excessively large, the fanout wire 14 connected to the longer drive signal line 11 is the first fanout wire 141, to adjust the panel resistance Rtotal, and the panel resistance Rtotal is prevented from exceeding the set impedance threshold value. In another aspect, in the direction from the edge of the display panel to the center of the display panel, the lengths of the fanout wires 14 gradually decrease. Thus in this embodiment, the first fanout wires 141 may be located at a side of the second fanout wires 142 away from the center of the display panel, thereby increasing the width of the longer fanout wire 14, reducing the impedance value of the touch wire, and improving touch performance.

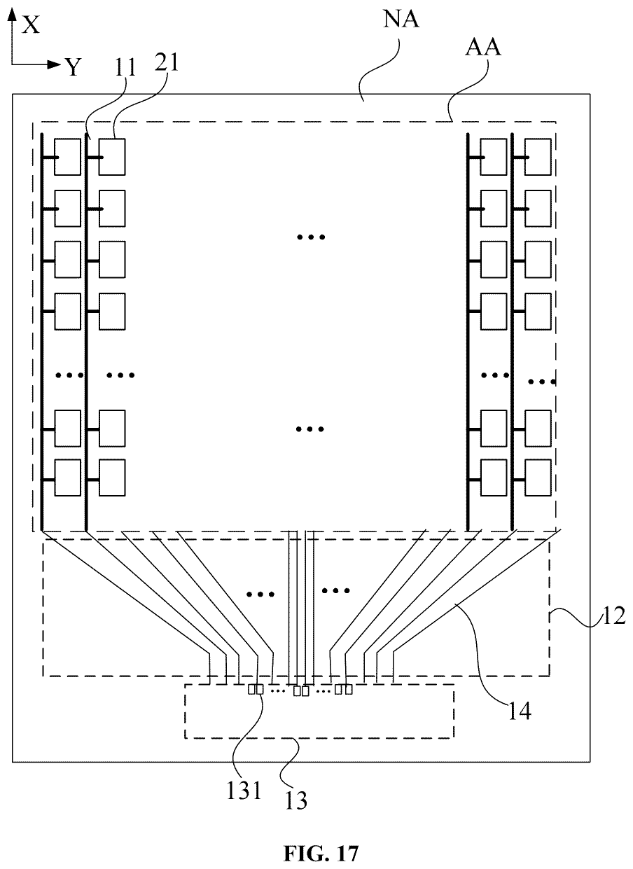

FIG. 17 is a schematic structural diagram of another display panel according to an embodiment of the present disclosure. In each of the embodiments described above, illustration is made by taking it as an example that the drive signal line 11 is a touch signal line. In this embodiment, as shown in FIG. 17, the drive signal line 11 may be a data signal line, and in this case, what the drive signal line 11 is connected to is a sub-pixel 21. The connection terminal region 13 transmits a data signal to a corresponding fanout wire 14 by a connection terminal 131, and the fanout wire 14 is configured to transmit the data signal in turn to the sub-pixel 21. In this embodiment, a length difference between the data signal lines is not large. In this embodiment, in the second direction Y and in the direction from the edge of the display panel to the center of the display panel, the widths of the first fanout wires may gradually decrease, or the lengths of the first wire segments of the first fanout wires may gradually decrease, to ensure that the panel impedances do not exceed the threshold value and also the narrow border of the display panel is achieved.

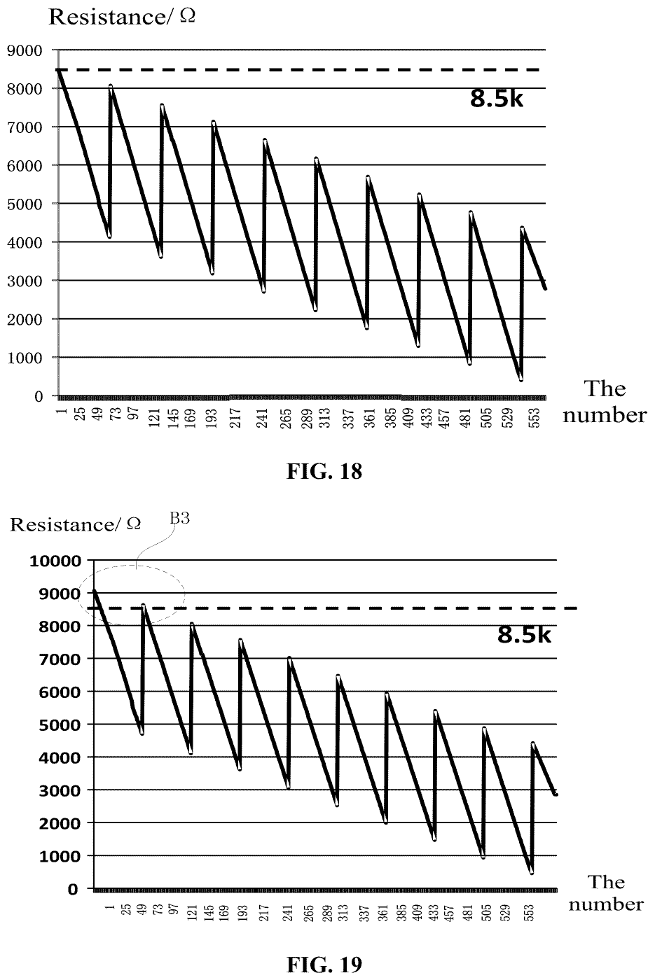

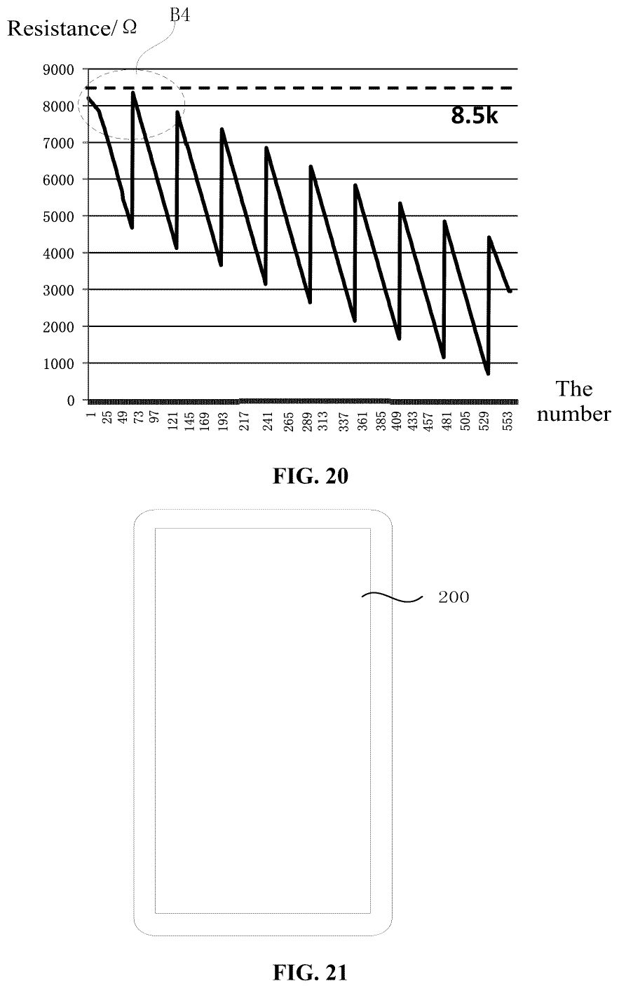

In some embodiments, it is required to take the effect of practical technique capability into account in calculation of impedance, that is, an adverse effect of a potential technique fluctuation on the impedance of the wire is required to be taken into consideration. If a set wire width is W′, considering the width caused by technique fluctuation ΔW′, the actual wire width is W′+ΔW′. ΔW′ may be positive, or may be negative, that is, the wire may be widened, or may be excessively thin. In the process of the calculation of the actual wire impedance, the effect of the narrowed wire should be considered and compensation should be provided to allow the compensated wire to meet the requirements of distribution line impedance. The set impedance threshold value of the touch IC (driver chip) of this embodiment takes 8.5 kΩ (8500Ω) as an example. As shown in FIG. 18 and FIG. 19, FIG. 18 is a schematic diagram of the impedance of the panel resistance in a normal technique according to an embodiment of the present disclosure, and FIG. 19 is a schematic diagram of the impedance of the panel resistance with technique fluctuations according to an embodiment of the present disclosure. In a normal technique condition, Rtotal=Raa+Rfanout; and Rtotal<8.5 k≤2 meets requirements of a touch IC. For the technique that may cause increase of impedance, impact of the technique fluctuation is to be taken into account into calculation of impedance. As shown in FIG. 19, Rtotal=Raa+Rfanout>8.5 kΩ at the B3 position, which adversely affects performance debugging of an active stylus. In this example, it can be found through calculation that fifteen fanout wires in total exceed the specification of 8.5 kΩ. Therefore, it is required to compensate the fifteen fanout wires. For example, for the fifteen fanout wires that are required to be compensated, the to-be-compensated length of an i-th wire is longer or shorter than the to-be-compensated length of an (i+1)-th wire by L/N. L is the length of the fanout wire. Therefore, the compensation range of the first fanout wire is 15/15×L, that is, 100% L, and the whole length of the fanout wire is to be compensated; the compensation range of the second wire is (15-1)/15×L, that is, 93% L; and the compensation range of the last wire is (15-14)/15×L, that is, 6.67% L. In the fifteen fanout wires to be compensated, the impedance difference between the compensated adjacent wires is 6.7%, and the impedance difference between the last compensated wire and the wire without being compensated is also 6.7%. In this case, there is no abrupt change between impedances of adjacent wires. The impedance after being compensated in this manner is as shown in FIG. 20. FIG. 20 is a schematic diagram of the impedance of the panel resistance with compensation being performed according to an embodiment of the present disclosure, and the impedances that originally have serrated abrupt changes become smoother in FIG. 20. As shown in FIG. 20 at a position B4, the impedance difference between adjacent wires is small, and touch is more sensitive. With this embodiment, a technique fluctuation or a technique fluctuation caused by a new technology can be compensated, thereby improving reliability of the touch screen.

A display device is further provided according to an embodiment of the present disclosure. FIG. 21 is a schematic structural diagram of a display device according to an embodiment of the present disclosure. As shown in FIG. 21, the display device according to the embodiment of the present disclosure includes a display panel 200 described in any embodiment of the present disclosure. The display device may be a mobile phone as shown in FIG. 21, or may be a computer, a tablet, an in-vehicle display, a television, a smart wearable apparatus, or the like, which is not specifically limited in this embodiment.

What is claimed is:

1. A display panel, comprising: a display region and a non-display region at least partially surrounding the display region; wherein
a plurality of drive signal lines are arranged in the display region and extending to the non-display region; in the display region, the plurality of drive signal lines extend in a first direction and are arranged in a second direction; the first direction is intersected with the second direction;
a fanout region and a connection terminal region are disposed in the non-display region, and the connection terminal region is disposed at a side of the fanout region away from the display region; a plurality of fanout wires are arranged in the fanout region; a plurality of connection terminals are arranged in the connection terminal region; and each of first ends of the plurality of fanout wires is connected to a respective one of the plurality of drive signal lines, and each of second ends of the plurality of fanout wires is connected to a respective one of the plurality of connection terminals;
wherein the plurality of fanout wires comprise a first fanout wire and a second fanout wire; the first fanout wire comprises a first wire segment; the first wire segment has a width different from a width of the second fanout wire; and a length of the first wire segment is equal to at least a portion of a length of the first fanout wire.

2. The display panel according to claim 1, wherein a sum of a resistance of a fanout wire of the plurality of fanout wires and a resistance of a drive signal line connected to the fanout wire serves as a panel resistance of the fanout wire; and
a panel resistance of the first fanout wire is less than or equal to a set impedance threshold value.

3. The display panel according to claim 2, wherein the plurality of drive signal lines comprise a first drive signal line and a second drive signal line, the first drive signal line is connected to the first fanout wire, and the second drive signal line is connected to the second fanout wire; and
wherein the greater a resistance of the first drive signal line is, the greater the width of the first wire segment is to make the panel resistance of the first fanout wire less than the set impedance threshold value; or the smaller a resistance of the first drive signal line is, the smaller the width of the first wire segment is to make the panel resistance of the first fanout wire less than the set impedance threshold value.

4. The display panel according to claim 1, wherein the length of the first wire segment is equal to the whole length of the first fanout wire; and
a width of the first fanout wire is greater than the width of the second fanout wire.

5. The display panel according to claim 4, wherein the plurality of fanout wires comprise a plurality of first fanout wires, and at least one of the plurality of first fanout wires has a width different from a width of another one of the plurality of first fanout wires.

6. The display panel according to claim 1, wherein the length of the first wire segment is equal to a portion of the length of the first fanout wire; and
the width of the first wire segment is greater than the width of the second fanout wire.

7. The display panel according to claim 6, wherein a plurality of adjacent first fanout wires are provided in a fourth direction, and the fourth direction is intersected with the second direction; and
along the fourth direction and in a direction from an edge of the display panel to a center of the display panel, lengths of first wire segments of the plurality of adjacent first fanout wires gradually decrease.

8. The display panel according to claim 6, wherein N adjacent first fanout wires are provided in a fourth direction, the fourth direction is intersected with the second direction, and the N adjacent first fanout wires each have a length L; and
along the fourth direction and in a direction from an edge of the display panel to a center of the display panel, a first wire segment of an i-th first fanout wire in the N adjacent first fanout wires has a length of L×(N+1−i)/N, wherein 1≤i≤N, i and N are positive integers, and N≥2.

9. The display panel according to claim 6, wherein the first fanout wire further comprises a second wire segment; and
the width of the first wire segment is greater than a width of the second wire segment, and the width of the second wire segment is the same as the width of the second fanout wire.

10. The display panel according to claim 9, wherein on a same first fanout wire, the first wire segment is connected to the second wire segment by a bevel.

11. The display panel according to claim 6, further comprising: a first metal layer and a second metal layer;
wherein the plurality of fanout wires comprise a first wire part and a second wire part; the first wire part is arranged in the first metal layer, the second wire part is arranged in the second metal layer, and the first wire part and the second wire part are connected by a connection hole between the first metal layer and the second metal layer.

12. The display panel according to claim 11, wherein the first wire segment is arranged in a first wire part of the first fanout wire;
N adjacent first fanout wires are provided in a fourth direction, the fourth direction is intersected with the second direction, and first wire parts of the N adjacent first fanout wires each have a length L1; and
along the fourth direction and in a direction from an edge of the display panel to a center of the display panel, a first wire segment in a first wire part of an i-th first fanout wire in the N adjacent first fanout wires has a length of L1×(N+1−i)/N, wherein 1≤i≤N, i and N are positive integers, and N≥2.

13. The display panel according to claim 11, wherein the first wire segment is arranged in a second wire part of the first fanout wire;
N adjacent first fanout wires are provided in a fourth direction, the fourth direction is intersected with the second direction, and second wire parts of the N adjacent first fanout wires each have a length L2; and
along the fourth direction and in a direction from an edge of the display panel to a center of the display panel, a first wire segment in a second wire part of an i-th first fanout wire in the N adjacent first fanout wires has a length of L2×(N+1−i)/N, wherein 1≤i≤N, i and N are positive integers, and N≥2.

14. The display panel according to claim 11, wherein the first wire segment is arranged in both a first wire part and a second wire part of the first fanout wire;
N adjacent first fanout wires are provided in a fourth direction, the fourth direction is intersected with the second direction, first wire parts of the N adjacent first fanout wires each have a length L1, and second wire parts of the N adjacent first fanout wires each have a length L2; and
along the fourth direction and in a direction from an edge of the display panel to a center of the display panel, a first wire segment of an i-th first fanout wire in the N adjacent first fanout wires has a length of (L1+L2)×(N+1−i)/N, wherein 1≤i≤N, i and N are positive integers, and N≥2.

15. The display panel according to claim 11, wherein the first metal layer also serves as a gate layer of a pixel driving circuit, and the second metal layer also serves as a source and drain layer of the pixel driving circuit.

16. The display panel according to claim 1, wherein a length of the display panel in the second direction is greater than a length of the display panel in the first direction; and
the fanout region and the connection terminal region are disposed in an edge region of the display panel, and along an opposite direction of the first direction, the fanout region and the connection terminal region are disposed on a side away from the display region.

17. The display panel according to claim 1, wherein along the second direction, the first fanout wire is arranged at a side of the second fanout wire away from a center of the display panel.

18. The display panel according to claim 1, wherein the plurality of connection terminals are configured to connect a driver chip; or
the plurality of connection terminals are configured to connect a driver chip through a flexible printed circuit board.

19. A display device, comprising: a display panel;
wherein the display panel, comprising: a display region and a non-display region at least partially surrounding the display region; wherein
a plurality of drive signal lines are arranged in the display region and extending to the non-display region; in the display region, the plurality of drive signal lines extend in a first direction and are arranged in a second direction; the first direction is intersected with the second direction;
a fanout region and a connection terminal region are disposed in the non-display region, and the connection terminal region is disposed at a side of the fanout region away from the display region; a plurality of fanout wires are arranged in the fanout region; a plurality of connection terminals are arranged in the connection terminal region; and each of first ends of the plurality of fanout wires is connected to a respective one of the plurality of drive signal lines, and each of second ends of the plurality of fanout wires is connected to a respective one of the plurality of connection terminals;
wherein the plurality of fanout wires comprise a first fanout wire and a second fanout wire; the first fanout wire comprises a first wire segment; the first wire segment has a width different from a width of the second fanout wire; and a length of the first wire segment is equal to at least a portion of a length of the first fanout wire;
wherein the plurality of connection terminals are configured to connect a driver chip.

20. The display device according to claim 19, wherein a sum of a resistance of a fanout wire of the plurality of fanout wires and a resistance of a drive signal line connected to the fanout wire serves as a panel resistance of the fanout wire; and
a panel resistance of the first fanout wire is less than or equal to a set impedance threshold value.
